(19) United States
(12) Patent Application Publication
(10) Pub. No.: US 2025/0336616 A1
(43) Pub. Date: Oct. 30, 2025

(54) INTEGRATED CIRCUIT STRUCTURES WITH BACKEND NANOELECTROMECHANICAL SYSTEM SWITCHES

(71) Applicant: Intel Corporation, Santa Clara, CA (US)

(72) Inventors: Abhishek A. Sharma, Portland, OR (US); Wilfred Gomes, Portland, OR (US); Tahir Ghani, Portland, OR (US); Anand S. Murthy, Portland, OR (US); Sagar Suthram, Portland, OR (US); Pushkar Sharad Ranade, San Jose, CA (US)

(73) Assignee: Intel Corporation, Santa Clara, CA (US)

(21) Appl. No.: 18/645,755

(22) Filed: Apr. 25, 2024

(51) Int. Cl. H01H 1/00; H01L 23/528

(52) U.S. Cl. CPC H01H 1/0094; H01L 23/5283

(57) ABSTRACT

Disclosed herein are NEMS switches embedded in backend layers of IC structures (backend NEMS switches). A backend NEMS switch includes one or more moveable nanoscale cantilevers that can be actuated to make or break electrical connections, thus controlling the flow of electrical current. Cantilevers may be suspended or anchored between electrodes and can be moved or deflected by applying electrical, mechanical, or thermal stimuli. An example IC structure may include an insulator material, first and second interconnects embedded in the insulator material, and a backend NEMS switch. The backend NEMS switch may include a middle element, a cantilever extending from the middle element, and one or more control elements. The middle element is connected to the first interconnect and, depending on a stimulus applied to the one or more control elements, the cantilever is either electrically connected to or electrically disconnected from the second interconnect.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component becomes increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1J provide schematic illustrations of integrated circuit (IC) structures in which backend nanoelectromechanical system (NEMS) switches may be implemented, according to some embodiments of the present disclosure.

FIGS. 2A-2B illustrate example cross-sectional side and top-down views of a backend NEMS switch, according to some embodiments of the present disclosure.

FIGS. 3A-3E illustrate example cross-sectional side views of an IC structure with a backend NEMS switch in different connection states, according to some embodiments of the present disclosure.

FIG. 4 illustrates top views of a wafer and dies that may include one or more IC structures with one or more backend NEMS switches, according to some embodiments of the present disclosure.

FIG. 5 illustrates a cross-sectional side view of an IC device assembly that may include one or more backend NEMS switches in accordance with any of the embodiments disclosed herein.

FIG. 6 is a block diagram of an example computing device that may include one or more IC structures with one or more backend NEMS switches in accordance with any of the embodiments disclosed herein.

FIG. 7 is a block diagram of an example processing device that may include one or more IC structures with one or more backend NEMS switches in accordance with any of the embodiments disclosed herein.

### DETAILED DESCRIPTION

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating IC structures with backend NEMS switches, described herein, it might be useful to first understand phenomena that may come into play in certain IC arrangements. The following foundational information may be viewed as a basis from which the present disclosure may be properly explained. Such information is offered for purposes of explanation only and, accordingly, should not be construed in any way to limit the broad scope of the present disclosure and its potential applications.

Front-end-of-line (FEOL) and back-end-of-line (BEOL) are two distinct stages in semiconductor manufacturing (e.g., in advanced complementary metal-oxide-semiconductor (CMOS) processes), each playing an important role in the fabrication of IC structures (or, more generally, of semiconductor devices). These terms refer to the chronological order of processes involved in creating an IC structure. The FEOL processes occur at the front or early stages of semiconductor manufacturing, typically on the surface of a semiconductor (e.g., silicon) wafer. In the FEOL, individual semiconductor devices components (e.g., transistor, capacitors, resistors, etc.) can be patterned in a wafer. In the BEOL, interconnect structures such as conductive lines and conductive vias, separated as needed by an insulator material, can be formed provide connection between individual components. The BEOL usually starts with forming the first metal layer on the wafer. The first metal layer is often called M0. More metal layers can be formed on top of M, and these metal layers are often called M1, M2, and so on. The BEOL layers comprising interconnect structures separated by an insulator material are typically referred to as “backend layers.”

Conventionally, once the interconnect structures are formed in the backend layers, the interconnections are set and cannot be changed. Embodiments of the present disclosure are based on recognition that one or more NEMS switches may be embedded in one or more of the backend layers to enable modification of the electrical connections based on stimuli applied to the NEMS switches, thus increasing the versatility of the backend interconnect structures and improving performance of IC structures. Because such NEMS switches are implemented in the backend, they are referred to herein as “backend NEMS switches.” A NEMS switch is a type of electromechanical switch that operates at the nanoscale. It is similar to a microelectromechanical systems (MEMS) switch but operates on an even smaller scale, typically with feature sizes on the order of nanometers. Backend NEMS switches described herein may utilize mechanical motion at the nanoscale to control the flow of electrical current. An example backend NEMS switch includes one or more moveable nanoscale elements, referred to herein as “cantilevers,” that can be actuated to make or break electrical connections, thus controlling the flow of electrical current. Cantilevers may be suspended or anchored between electrodes and can be moved or deflected by applying electrical, mechanical, or thermal stimuli. An example IC structure may include an insulator material, first and second interconnects embedded in the insulator material, and a backend NEMS switch. The backend NEMS switch may include a middle element, a cantilever extending from the middle element, and one or more control elements, e.g., one or more control elements separated from the cantilever by a gap. The middle element is connected to the first interconnect and, depending on a stimulus applied to the one or more control elements, the cantilever is either electrically connected to or electrically disconnected from the second interconnect. In various embodiments, the stimuli applied to the one or more control elements could be electrical, mechanical, or thermal, for example. When actuated, the cantilever of a backend NEMS switch may move to physically open or close the electrical circuit, thereby controlling the flow of current. Backend NEMS switches described herein can exhibit extremely fast switching speeds, low power consumption, and high on/off ratios, making them promising candidates for use in backends of IC structures where miniaturization and high performance are critical.

In the following detailed description, various aspects of the illustrative implementations may be described using terms commonly employed by those skilled in the art to convey the substance of their work to others skilled in the art. For example, the term “connected” means a direct electrical connection between the things that are connected (e.g., with the things being in electrically conductive and/or physical contact, e.g., with the things being in direct electrically conductive and/or direct physical contact), without any intermediary devices, while the term “coupled” means either a direct electrical connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−20%, e.g., within +/−5% or within +/−2% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

Although certain elements may be referred to in the singular herein, such elements may include multiple sub-elements. For example, “an insulator material” may include one or more insulator materials. The term “insulating” and variations thereof (e.g., “insulative” or “insulator”) means “electrically insulating,” the term “conducting” and variations thereof (e.g., “conductive” or “conductor”) means “electrically conducting,” unless otherwise specified. For example, the term “insulator material” may refer to solid materials (and/or liquid materials that solidify after processing as described herein) that are substantially electrically non-conducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. With reference to optical signals and/or devices, components and elements that operate on or using optical signals, the term “conducting/conductive” can also mean “optically conducting/conductive.”

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

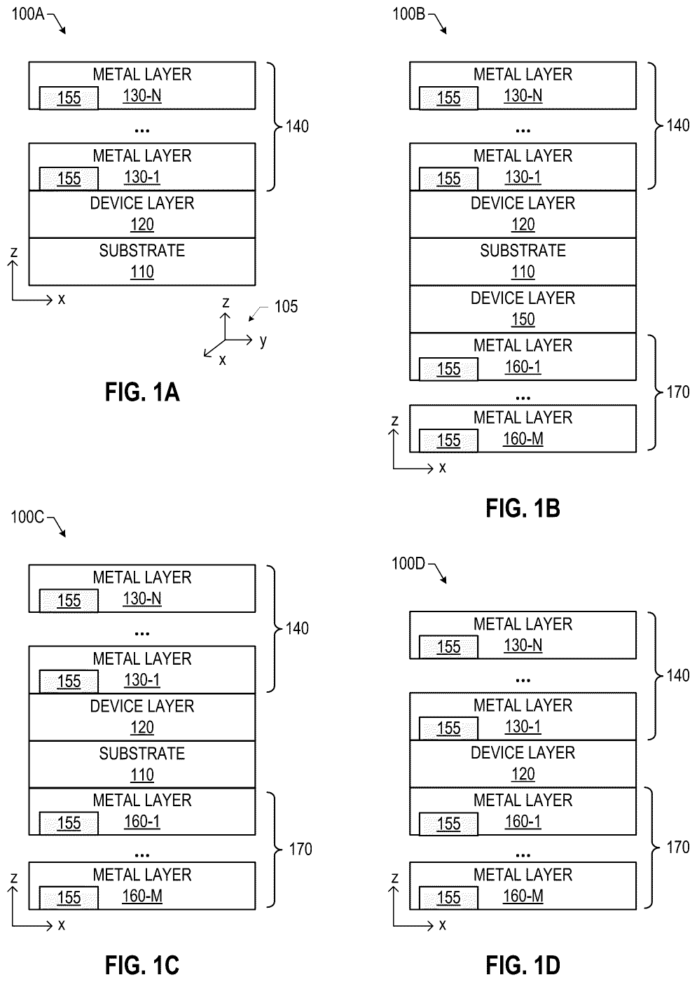

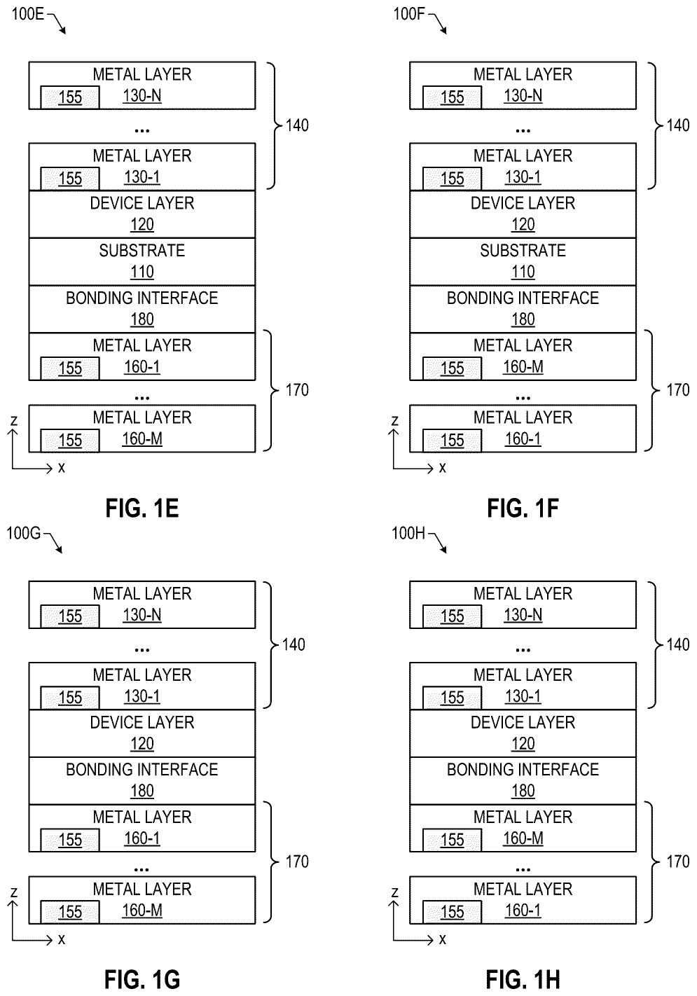

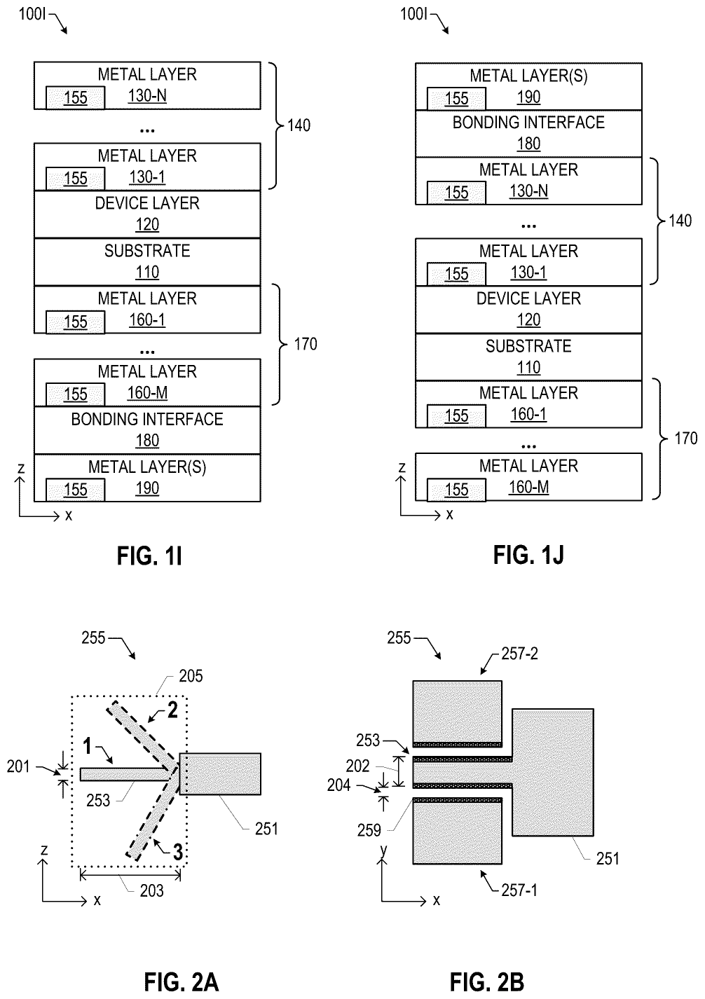

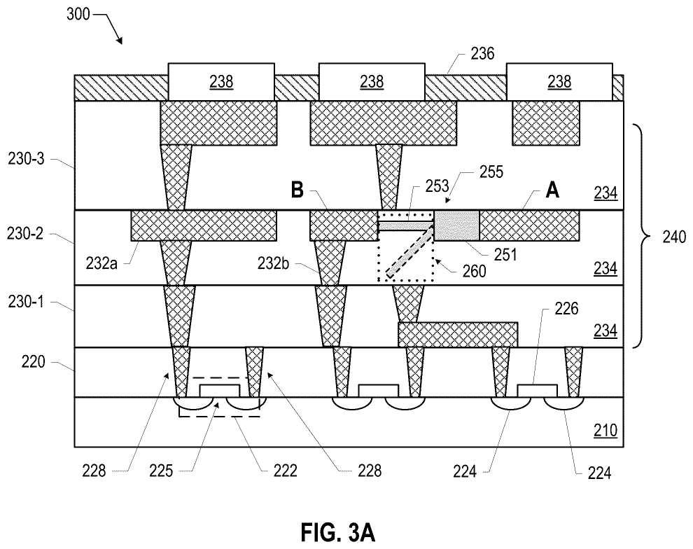

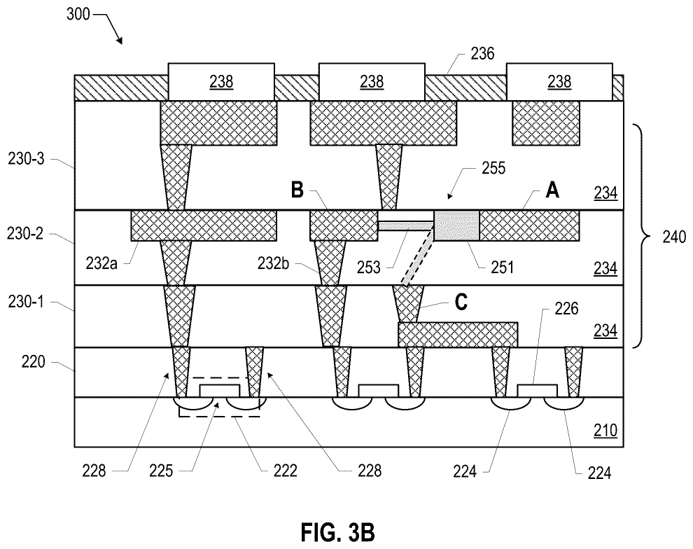

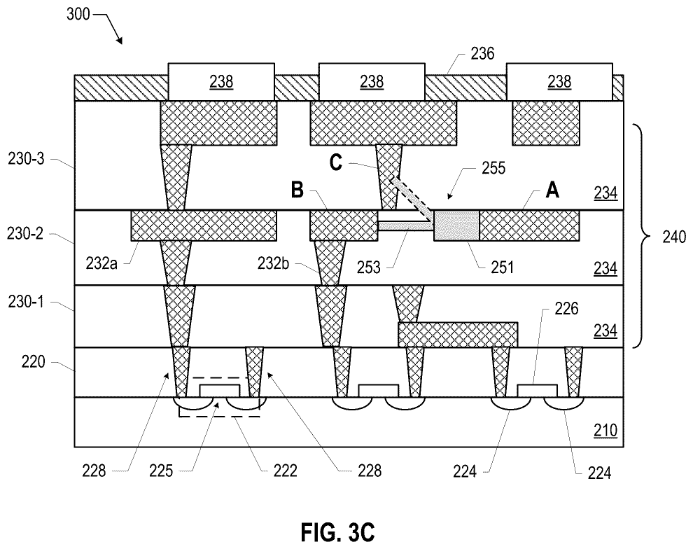

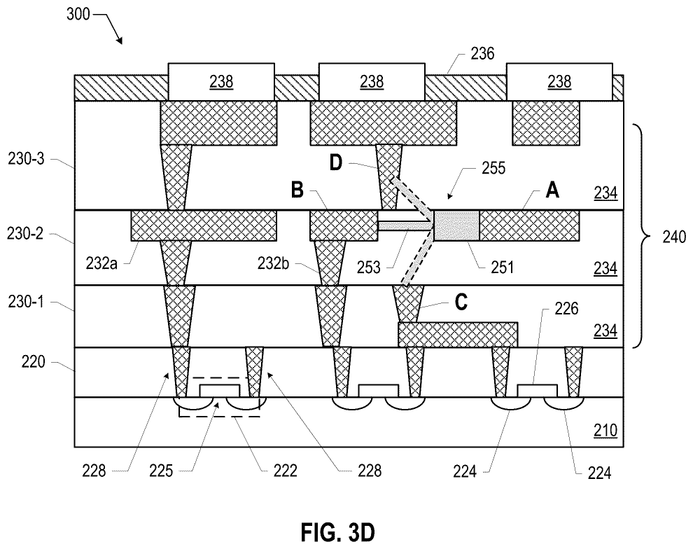

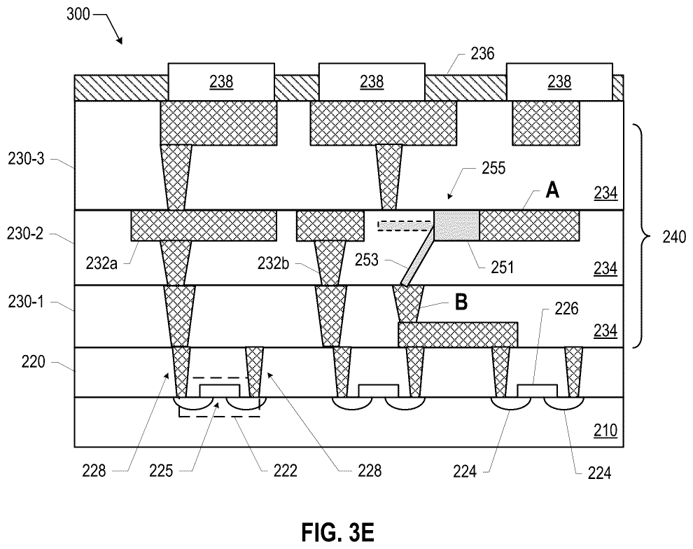

Any of the features discussed with reference to any of accompanying drawings herein may be combined with any other features to form IC structures with one or more backend NEMS switches, as appropriate. A number of elements of the drawings are shared with others of the drawings; for ease of discussion, a description of these elements is not repeated, and these elements may take the form of any of the embodiments disclosed herein. If multiple instances of certain elements are illustrated, then, in some cases, to not clutter the drawings only some of these elements may be labeled with a reference sign and other ones of these elements are not labeled (e.g., although FIG. 2A illustrates multiple conductive lines 232a and multiple conductive vias 232b, only one of each is labeled with a reference sign). However, in other cases, for ease of explanation, different instances of a given element in a single drawing may be referred to with numbers 1, 2, and so on, after a dash (e.g., FIG. 1A illustrates two metal layers, labeled individually as a metal layer 130-1 and 130-N, where N is an integer greater than one). For convenience, the phrase “FIG. 1” may be used to refer to the collection of drawings of FIGS. 1A-1J, the phrase “FIG. 2” may be used to refer to the collection of drawings of FIGS. 2A-2B, and the phrase “FIG. 3” may be used to refer to the collection of drawings of FIGS. 3A-3E. Similarly, the phrase “IC structures 100” may be used to refer to a collection of IC structures 100A-100J of FIGS. 1A-1J, and so on.

The drawings are not necessarily to scale. In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures with backend NEMS switches as described herein.

Various IC structures with backend NEMS switches as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

FIGS. 1A-1J provide schematic illustrations of IC structures in which backend NEMS switches proposed herein may be implemented, according to some embodiments of the present disclosure.

FIG. 1A illustrates a cross-sectional view of an example IC structure 100A in which one or more backend NEMS switches 155 may be implemented, according to some embodiments of the present disclosure, and one example implementation of the IC structure 100A is an IC structure 300 shown in FIGS. 3A-3E, according to some embodiments of the present disclosure. FIG. 1A illustrates an example coordinate system 105 with axes x-y-z so that the various planes illustrated in FIGS. 1A and 1n some subsequent drawings may be described with reference to this coordinate system.

As shown in FIG. 1A, in general, the IC structure 100A may include a substrate 110, a device layer 120, and a plurality of metal layers 130, individually labeled as a metal layer 130-1 through metal layer 130-N, where N is an integer greater than 1. Together, the metal layers 130 may be referred to as a metallization stack 140. The illustration of FIG. 1A is intended to provide a general orientation and arrangement of various layers with respect to one another, and, unless specified otherwise in the present disclosure, includes embodiments of the IC structure 100A where portions of elements described with respect to one of the layers shown in FIG. 1A may extend into one or more, or be present in, other layers. Same applies to the subsequent drawings.

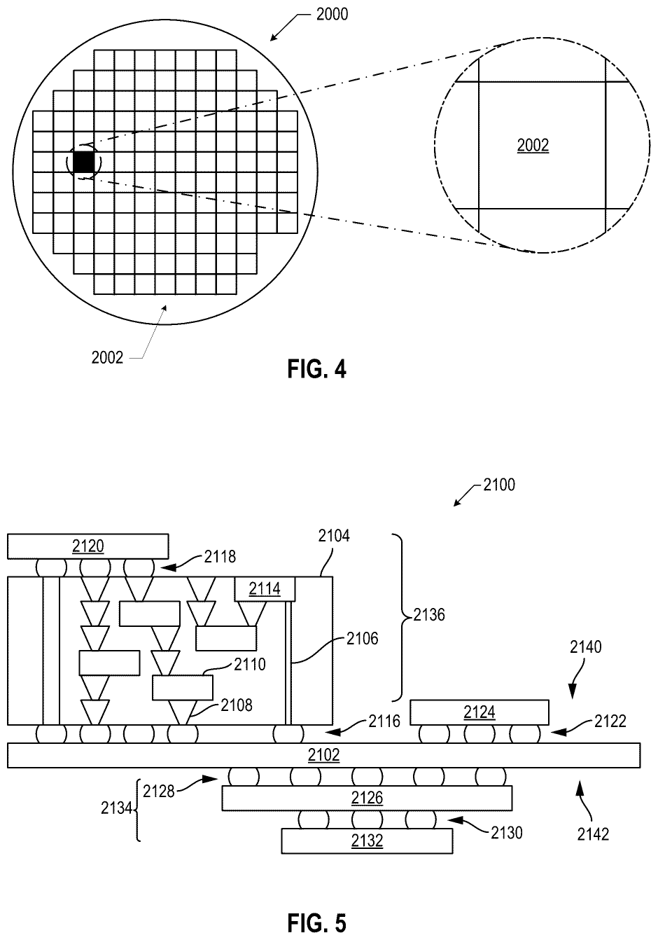

The substrate 110 may be any suitable support over which the device layer 120 and the metallization stack 140 may be provided. For example, the substrate 110 may be a die, a wafer, a chip, or any other suitable support structure. The substrate 110 may, e.g., be the wafer 2000 of FIG. 4, discussed below, and may be, or be included in, a die, e.g., the singulated die 2002 of FIG. 4, discussed below. The substrate 110 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the substrate 110 may be a printed circuit board (PCB) substrate. Although a few examples of materials from which the substrate may be formed are described here, any material that may serve as a foundation upon which a semiconductor device implementing any of the backend NEMS switches as described herein may be built falls within the spirit and scope of the present disclosure.

The device layer 120 may include any combination of components (e.g., ICs) provided over the substrate 110. For example, in some embodiments, the device layer 120 may include various logic layers, circuits, and devices (e.g., logic transistors) to drive and control a logic IC. In some embodiments, the device layer 120 may include memory devices/circuits. The device layer 120 may also be referred to as a “FEOL layer” and the components of the device layer 120 (e.g., transistors) may be referred to as “frontend components.”

Various layers of the metallization stack 140 may be, or include, BEOL layers, which may also be referred to as “backend layers.” As used herein, the term “metal layer” may refer to a layer above a substrate 110 that includes electrically conductive interconnect structures (e.g., conductive lines and conductive vias) for providing electrical connectivity between different IC components, e.g., between different components of the device layer 120. Metal layers described herein may also be referred to as “metal layers” to indicate that these layers include electrically conductive interconnect structures which may, but does not have to, be metal. Various metal layers of the metallization stack 140 may be used to interconnect the various inputs and outputs of the active components (e.g., transistors) in the device layer 120. Generally speaking, each of the metal layers of the metallization stack 140 may include a conductive line (also sometimes referred to as a “trench,” a “trace,” or a “metal line”) and/or a conductive via. Conductive lines of a metal layer are interconnects configured for transferring signals and power along electrically conductive (e.g., metal) structures extending in the x-y plane (e.g., in the x or y directions), while the conductive vias of a metal layer are configured for transferring signals and power through electrically conductive structures extending in the z-direction, e.g., to any of the adjacent metal layers above or below. Accordingly, conductive vias connect interconnect structures (e.g., conductive lines and/or conductive vias) of one metal layer to interconnect structures of an adjacent metal layer. While referred to as “metal” layers, various layers of the metallization stack 140 may include only certain patterns of conductive metals, e.g., copper (Cu), aluminum (Al), tungsten (W), or cobalt (Co), or metal alloys, or more generally, patterns of an electrically conductive material, formed in a medium of an insulator material such as an interlayer dielectric (ILD). The insulator medium may include any suitable ILD materials such as silicon oxide, carbon-doped silicon oxide, silicon carbide, silicon nitride, aluminum oxide, and/or silicon oxynitride.

As shown in FIG. 1A, in some embodiments, backend NEMS switches 155 may be provided in the metal layers 130-1 and 130-N of the metallization stack 140. In some embodiments, more than one backend NEMS switches 155 may be provided in one of the metal layers 130 of the metallization stack 140. In some embodiments, one or more backend NEMS switches 155 may be provided in only some but not all of the metal layers 130 of the metallization stack 140.

FIG. 1B illustrates a cross-sectional view of an example IC structure 100B in which one or more backend NEMS switches 155 may be implemented, according to some embodiments of the present disclosure. The IC structure 100B is similar to the IC structure 100A in that it may include the substrate 110, the device layer 120, and the metallization stack 140 comprising the metal layers 130, as described above. In addition, as shown in FIG. 1B, the IC structure 100B further includes a device layer 150 and metal layers 160, individually labeled as a metal layer 160-1 through a metal layer 160-M, where M is an integer equal to or greater than 1 and may, but does not have to be, equal to N. Together, the metal layers 160 may be referred to as a metallization stack 170. The side of the substrate 110 on which the device layer 120 is provided is typically referred to as a front side, and the other side of the substrate 110 is referred to as a back side. Thus, the device layer 120 and the metal layers 130 are frontside layers, while the device layer 150 and the metal layers 160 are backside layers. As shown in FIG. 1B, the substrate 110 may be between the device layer 120 on the front side and the device layer 150 on the back side, the device layer 120 may be between the substrate 110 and the metallization stack 140, and the device layer 150 may be between the substrate 110 and the metallization stack 170.

Similar to the device layer 120, the device layer 150 may include any combination of components (e.g., ICs) provided over the back side of the substrate 110. For example, in some embodiments, the device layer 150 may include various logic layers, circuits, and devices (e.g., logic transistors) to drive and control a logic IC. In some embodiments, the device layer 150 may include memory devices/circuits. The device layer 150 may also be referred to as a “backside device layer” and the components of the device layer 150 (e.g., transistors) may be referred to as “backside components.” Other descriptions provided with respect to the device layer 120 are applicable to the device layer 150 and, in the interest of brevity, are not repeated. Various layers of the metallization stack 170 may be, or include, BEOL layers on the back side of the substrate 110, which may also be referred to as “backside backend layers.” Other descriptions provided with respect to the metal layers 130 and the metallization stack 140 are applicable to, respectively, the metal layers 160 and the metallization stack 170 and, in the interest of brevity, are not repeated.

The device layer 150 and the metal layers 160 may be monolithically integrated on the back side of the IC structure 100B, which may be recognized by the lack of a bonding layer or a bonding interface between the back side of the substrate 110 and the device layer 150. To that end, once the fabrication of various layers on the front side of the IC structure 100B has been completed, the IC structure 100B may be flipped upside down and fabrication of the device layer 150 and, subsequently, of the metal layers 160 may proceed in the similar manner but on the back side of the IC structure 100B. Further indicative of the monolithic integration, cross-sectional shapes (e.g., in a cross-section of the IC structure 100B in a plane substantially perpendicular to the device layer 120, e.g., a plane as shown in FIGS. 3A-3E) of at least some of the interconnect structures on the back side may be different from those of some of the interconnect structures on the front side.

As shown in FIG. 1B, in some embodiments, backend NEMS switches 155 may be provided in the metal layers 160-1 and 160-N of the metallization stack 170 at the back side of the IC structure 100B. In some embodiments, more than one backend NEMS switches 155 may be provided in one of the metal layers 160 of the metallization stack 170. In some embodiments, one or more backend NEMS switches 155 may be provided in only some but not all of the metal layers 160 of the metallization stack 170. In some embodiments where both the metallization stack 140 and the metallization stack 170 are present, e.g., as is the case for the IC structure 100B, one or more backend NEMS switches 155 may be provided only in the metallization stack 140 but not in the metallization stack 170, or vice versa. In other embodiments, one or more backend NEMS switches 155 may be provided both in the metallization stack 140 and in the metallization stack 170. Other descriptions provided with respect to FIG. 1A are applicable to FIG. 1B and, in the interest of brevity, are not repeated.

FIG. 1C illustrates a cross-sectional view of an example IC structure 100C in which one or more backend NEMS switches 155 may be implemented, according to some embodiments of the present disclosure. The IC structure 100C is similar to the IC structure 100B except that the IC structure 100C does not include the device layer 150 at the back side of the substrate 110. Instead, the metal layers 160 are provided directly over the back side of the substrate 110. Thus, as shown in FIG. 1C, the substrate 110 may be between the device layer 120 on the front side and the metal layers 160 on the back side, and, as in FIG. 1B, the device layer 120 may be between the substrate 110 and the metallization stack 140. Other descriptions provided with respect to FIG. 1B are applicable to FIG. 1C and, in the interest of brevity, are not repeated.

FIG. 1D illustrates a cross-sectional view of an example IC structure 100D in which one or more backend NEMS switches 155 may be implemented, according to some embodiments of the present disclosure. The IC structure 100D is similar to the IC structure 100C except that, in the IC structure 100D, once all of the layers on the front side have been fabricated and the IC structure 100D has been flipped over to continue with fabrication of the metal layers 160 on the back side, the substrate 110 may be thinned (e.g., polished, etched, or otherwise removed) to the point that terminals of the components of the device layer 120 (e.g., S/D regions of the transistors in the device layer 120) may be contacted from the back side. The metal layers 160 may then be provided directly over the back side of the device layer 120. Thus, as shown in FIG. 1D, the substrate 110 may be substantially removed (but the portions of the substrate 110 in which the frontend devices of the device layer 120 were fabricated remain), and the device layer 120 may be between the metal layers 130 on the front side and the metal layers 160 on the back side. Other descriptions provided with respect to FIG. 1C are applicable to FIG. 1D and, in the interest of brevity, are not repeated

FIGS. 1A-1D illustrate example embodiments where the metal layers 160 on the back side are provided by monolithic integration. In other embodiments, the metal layers 160 on the back side may be provided using hybrid bonding of separate IC structures together, as shown in FIGS. 1E-1H. FIG. 1E-1H illustrate cross-sectional views of, respectively, example IC structures 100E-100H in which one or more backend NEMS switches 155 may be implemented, according to some embodiments of the present disclosure.

In general, hybrid bonding is described herein with reference to the metal layers 160 being fabricated on a separate IC structure and then bonded to the back side of the substrate 110, e.g., using a bonding material. When the bottom side of the metal layers 160 is bonded to the back side of the substrate 110 (e.g., after a support over which the metal layers 160 are fabricated is thinned down), the bonding may be described to as “back-to-back” (b2b), an example of which is shown in FIG. 1E. When the top side of the metal layers 160 is bonded to the back side of the substrate 110, the bonding may be described to as “front-to-back” (f2b), an example of which is shown in FIG. 1F. Continuing with the designation of the individual metal layers 160 used herein, where the metal layer 160-1 is the one fabricated first (i.e., the metal layer that is below all other metal layers of the metal layers 160), FIG. 1E illustrates that the metal layer 160-1 is closest to the device layer 120 and the metal layer 160-M is farthest from the device layer 120, representing the b2b bonding. Analogously, FIG. 1F illustrates that the metal layer 160-M is closest to the device layer 120 and the metal layer 160-1 is farthest from the device layer 120, representing the f2b bonding.

As a result of performing hybrid bonding, a bonding interface 180 may be present in the final IC structures. In the IC structure 100E of FIG. 1E, the bonding interface 180 is present between a face of the metal layer 160-1 and a face (the back side) of the substrate 110 being bonded together. In the IC structure 100F of FIG. 1F, the bonding interface 180 is present between a face of the metal layer 160-M and a face (the back side) of the substrate 110 being bonded together.

In some embodiments, bonding of the back side of the substrate 110 and one of the metal layers metal layers 160 may be performing using insulator-insulator bonding, e.g., as oxide-oxide bonding, where an insulator material of the substrate 110 or an insulator material provided over the back side of the substrate 110 for the purposes of bonding is bonded to an insulator material of the one of the metal layers metal layers 160 being bonded to the back side of the substrate 110. In some embodiments, a bonding material may be present in between the faces that are bonded together (e.g., the bonding interface 180 in the IC structure 100E and the IC structure 100F may include a bonding material). To that end, the bonding material may be applied to the one or both faces that are to be bonded and then the faces are put together, possibly while applying a suitable pressure and heating up the assembly to a suitable temperature (e.g., to moderately high temperatures, e.g., between about 50 and 200 degrees Celsius) for a duration of time. In some embodiments, the bonding material may be an adhesive material that ensures attachment of the faces of different IC structures to one another. In some embodiments, the bonding material may be an etch-stop material. In some embodiments, the bonding material may be both an etch-stop material and have suitable adhesive properties to ensure attachment of the first and second IC structures to one another. In some embodiments, the bonding material may include silicon, nitrogen, and carbon, where the atomic percentage of any of these materials may be at least 1%, e.g., between about 1% and 50%, indicating that these elements are added deliberately, as opposed to being accidental impurities which are typically in concentration below about 0.1%. Having both nitrogen and carbon in these concentrations in addition to silicon is not typically used in conventional semiconductor manufacturing processes where, typically, either nitrogen or carbon is used in combination with silicon, and, therefore, could be a characteristic feature of the hybrid bonding. Using at the bonding interface 180 an etch-stop material that includes include silicon, nitrogen, and carbon, where the atomic percentage of any of these materials may be at least 1%, e.g., SiOCN, may be advantageous in terms that such a material may act both as an etch-stop material, and have sufficient adhesive properties to bond the back of the substrate 110 and one of the metal layers 160 together. In addition, using at the bonding interface 180 an etch-stop material that includes include silicon, nitrogen, and carbon, where the atomic percentage of any of these materials may be at least 1%, may be advantageous in terms of improving etch-selectivity of this material with respect to etch-stop materials that may be used in the layers provided over the front side of the substrate 110 and the metal layers 160 provided at the back side of the substrate 110.

In some embodiments, no bonding material may be used, but there will still be a bonding interface (e.g., the bonding interface 180 of the IC structures 100E or 100F) resulting from the bonding of one of the metal layers 160 and the back side of the substrate 110 to one another. Such a bonding interface may be recognizable as a seam or a thin layer in the microelectronic assembly, using, e.g., selective area diffraction (SED), even when the specific materials of the insulators of the one of the metal layers 160 and the back side of the substrate 110 that are bonded together may be the same, in which case the bonding interface would still be noticeable as a seam or a thin layer in what otherwise appears as a bulk insulator (e.g., bulk oxide) layer.

Other descriptions provided with respect to FIGS. 1A-1D are applicable to FIGS. 1E-1F and, in the interest of brevity, are not repeated.

The IC structures 100G and 100H, shown in, respectively, FIG. 1G and FIG. 1H, are similar to, respectively, the IC structures 100E and 100F, except that the substrate 110 is thinned and the bonding interface 180 is between the back side of the device layer 120 and one of the metal layers 160. All of the descriptions provided above with respect to bonding the back side of the substrate 110 and one of the metal layers 160 using the bonding interface 180 are applicable to bonding the back side of the device layer 120 and one of the metal layers 160 using the bonding interface 180 of the IC structures 100G and 100H and, in the interest of brevity, are not repeated here. Descriptions provided with respect to thinning of the substrate 110 provided above with reference to the IC structure 100D are also applicable to the IC structures 100G and 100H and, in the interest of brevity, are not repeated. Other descriptions provided with respect to FIGS. 1E-1F are applicable to FIGS. 1G-1H and, in the interest of brevity, are not repeated.

In still further embodiments, a combination of monolithically integrated and hybrid-bonded metal layers may be implemented. FIGS. 1I-1J illustrate example embodiments where the metal layers 160 on the back side are provided by monolithic integration, but metal layers 190 are hybrid-bonded, either to the back side (as shown in FIG. 1I) or to the front side (as shown in FIG. 1J). FIG. 1I-1J illustrate cross-sectional views of, respectively, example IC structures 100I and 100J in which one or more backend NEMS switches 155 may be implemented, according to some embodiments of the present disclosure.

The IC structures 100I and 100J, shown in, respectively, FIGS. 1I-1J, are similar to the IC structure 100C, except that they further include a bonding interface 180 and one more metal layers 190. In FIG. 1I, the bonding interface 180 and the one more metal layers 190 are on the back side of the device layer 120, e.g., the bonding interface 180 may be between the metal layer 160-M and the one more metal layers 190. In FIG. 1J, the bonding interface 180 and the one more metal layers 190 are on the front side of the device layer 120, e.g., the bonding interface 180 may be between the metal layer 130-N and the one more metal layers 190. All of the descriptions provided above with respect to bonding the one of the metal layers 160 using the bonding interface 180 are applicable to bonding the one more metal layers 190 as shown in FIGS. 1I and 1J and, in the interest of brevity, are not repeated here. The one more metal layers 190 may include structures (e.g., interconnects and/or capacitors) having a finer pitch than can be implemented in the metal layer 160-M if the one more metal layers 190 are bonded to the back side, or than can be implemented in the metal layer 130-N if the one more metal layers 190 are bonded to the front side of the device layer 120. In this manner, interconnects and/or capacitors with pitches smaller than those of metal layer underneath them may be implemented. Other descriptions provided with respect to FIG. 1C are applicable to FIGS. 1I-1J and, in the interest of brevity, are not repeated.

Although FIGS. 1I-1J illustrate the substrate 110 being present, as in the IC structure 100C of FIG. 1C, in other embodiments, the substrate 110 may be thinned and omitted from the IC structures 100I and 100J. In such embodiments, the IC structures 100I and 100J would be similar to the IC structure 100D of FIG. 1D, except that they further include a bonding interface 180 and one more metal layers 190 as described. Other descriptions provided with respect to FIG. 1D are applicable to FIGS. 1I-1J and, in the interest of brevity, are not repeated

FIGS. 2A-2B illustrate example cross-sectional side and top-down views of a backend NEMS switch 255, according to some embodiments of the present disclosure. The backend NEMS switch 255 is an example of any of the backend NEMS switches 155 of FIGS. 1A-1J.

As shown in FIGS. 2A-2B, a backend NEMS switch 255 may include a middle element 251, a cantilever 253 extending from the middle element, and one or more control elements 257 separated from the cantilever 253 by a gap. FIG. 2B illustrates two control elements 257, individually labeled as a control element 257-1 and a control element 257-2, on either side of the cantilever 253. In other embodiments, more than two control elements 257 may be provided for a cantilever 253.

The middle element 251, the cantilever 253, and the one or more control elements 257 may be formed of any suitable conductive material, such as aluminum, copper, titanium, nickel, or any suitable carbines or nitrides of one or more metals. In some embodiments, sidewalls of the cantilever 253 that are facing the one or more control elements 257 and/or sidewalls of the one or more control elements 257 that are facing the cantilever 253 may be coated with a high-k dielectric material 259 (shown in FIG. 2B) to increase the field between the cantilever 253 and the one or more control elements 257. In various embodiments, the dielectric constant (k) of the high-k dielectric material 259 may be between about 6-9 (e.g., if the high-k dielectric material 259 includes materials such as aluminum oxide or silicon nitride) and about 50, e.g., be between about 20 and 30 (e.g., if the high-k dielectric material 259 includes materials such as hafnium oxide or zirconium oxide).

The middle element 251, the cantilever 253, and the one or more control elements 257 may have any suitable dimensions. In some embodiments, a thickness 201 of the cantilever 253 may be between about 5 nanometers and about 250 nanometers, e.g., between about 10 nanometers and about 200 nanometers, while, in other embodiments, the thickness 201 of the cantilever 253 may be between about 500 nanometers and about 8 micron, e.g., between about 1 micron and about 5 micron. The thickness 201 may be in the larger range (e.g., between about 500 nanometers and about 8 micron) if the cantilever 253 is implemented in the higher levels of a metallization stack (e.g., the metallization stack 140 or the metallization stack 170), i.e., further away from the device layer (e.g., the device layer 120). In general, the further away from the device layer 120 is the cantilever 253 implemented in, the larger are the dimensions for the thickness 201. Other dimensions of the backend NEMS switch 255, e.g., a width 202 and a length 203 of the cantilever 253, a gap 204 between the cantilever 253 and one of the one or more control elements 257, and a thickness of the high-k dielectric material 259 may scale depending on the thickness 201. For example, in some embodiments, the width 202 of the cantilever 253 may be between about 5 times and 15 times larger than the thickness 201, e.g., about 10 times larger. In some embodiments, the length 203 of the cantilever 253 may be between about 1.5 times and 15 times larger than the width 202, e.g., between about 5 times and about 10 times larger. In some embodiments, the gap 204 may be up to about 10 times larger than the thickness 201. In some embodiments, the thickness of the high-k dielectric material 259 on the sidewalls of the cantilever 253 and/or the one or more control elements 257 may be between about 10% of the gap 204 and about 80% of the gap 204.

When the backend NEMS switch 255 is implemented in the backend of an IC structure, e.g., in the metallization stack 140 or in the metallization stack 170 or in one of the metal layers 190 of various embodiments of the IC structures 100, some portions of the backend NEMS switch 255 may be embedded in an insulator material. However, a void may surround at least a portion of the cantilever 253 to enable mechanical motion of the cantilever 253. FIG. 2A illustrates an embodiment where the cantilever 253 may be in one of three positions, or states. The first position is shown with the cantilever 253 illustrated with a solid line and labeled with a reference numeral 1. The second position is shown with the cantilever 253 illustrated with a dashed line and labeled with a reference numeral 2. The third position is shown with the cantilever 253 illustrated with a dash-dotted line and labeled with a reference numeral 3. In various embodiments, the void around the cantilever 253 is sufficient to accommodate the different positions of the cantilever 253. For example, an area shown in FIG. 2A within a dotted contour 205 may indicate a void around the cantilever 253.

When the backend NEMS switch 255 is implemented in the backend of an IC structure, e.g., in the metallization stack 140 or in the metallization stack 170 or in one of the metal layers 190, the middle element 251 may be connected to a first interconnect (e.g., to a first conductive line or conductive via) and, depending on a stimulus applied to the one or more control elements 257, the cantilever 253 may be either electrically connected to or electrically disconnected from a second interconnect (e.g., a second conductive line or conductive via). In some embodiments, the stimulus applied to the one or more control elements 257 could be an electrical stimulus such as voltage or current. In other embodiment, the stimulus applied to the one or more control elements 257 could be a mechanical stimulus (e.g., a mechanical force applied through electrostatic forces, piezoelectric effects, thermal expansion, or magnetic forces) or a thermal stimulus (e.g., a change in temperature). The operation of the backend NEMS switch 255 may rely on various principles of nanomechanics, including electrostatic forces, piezoelectric effects, and/or van der Waals interactions. When actuated, the cantilever 253 of the backend NEMS switch 255 may move to physically open or close the electrical circuit, thereby controlling the flow of current in an IC structure, e.g., in any of the IC structures 100, described above.

FIGS. 3A-3E illustrate example cross-sectional side views of an IC structure 300 with a backend NEMS switch 255 in different connection states in accordance with any of the embodiments disclosed herein. The IC structure 300 shown in FIGS. 3A-3E is an example of the IC structure 100A of FIG. 1A, but, in other embodiments, the IC structure 300 may be modified in accordance with the descriptions provided for FIGS. 1B-1J to realize other examples of IC structures with backend NEMS switches as described herein.

The IC structure 300 may be formed on a substrate 210, where the substrate 210 may be any suitable support structure as described herein, e.g., the substrate 110 of FIG. 1A and/or the wafer 2000 of FIG. 4. The substrate 210 may be part of a singulated die (e.g., the dies 2002 of FIG. 4) or a wafer (e.g., the wafer 2000 of FIG. 4).

The IC structure 300 may include one or more device layers 220 disposed on the substrate 210, where, together, the one or more device layers 220 may be an example of the device layer 120 of the IC structure 100A. The device layer 220 may include features of one or more transistors 222 (e.g., metal-oxide-semiconductor field-effect transistors (MOSFETs)) formed on the substrate 210, e.g., channel regions/portions of the transistors 222 may be portions of the uppermost layers of the substrate 210. The device layer 220 may include, for example, source and/or drain (S/D) regions 224, gates 226 to control current flow in the transistors 222 between their S/D regions 224, channel regions 225 between S/D regions 224 in each of the transistors 222, and S/D contacts 228 to route electrical signals to/from the S/D regions 224. The transistors 222 may include additional features not depicted for the sake of clarity, such as device isolation regions, gate contacts, and the like. The transistors 222 are not limited to the type and configuration depicted in FIG. 3 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

As shown in FIG. 3, a channel region 225 may be a region of a semiconductor material, between the first and second S/D regions 224 of the transistor 222, in which a channel of the transistor 222 forms during operation of the transistor 222. In general, the channel region 225 may be composed of semiconductor material systems including, for example, N-type or P-type materials systems. In some embodiments, the channel region 225 may include a substantially monocrystalline semiconductor, such as silicon (Si) or germanium (Ge). In some embodiments, the channel region 225 may include a compound semiconductor with a first sub-lattice of at least one element from group III of the periodic table (e.g., Al, Ga, In), and a second sub-lattice of at least one element of group V of the periodic table (e.g., P, As, Sb). In some embodiments, the channel region 225 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel region 225 may include a combination of semiconductor materials.

For some example N-type transistor embodiments (i.e., for the embodiments where a transistor 222 is an N-type metal-oxide-semiconductor (NMOS) transistor), the channel region 225 may include a III-V material having a relatively high electron mobility, such as, but not limited to InGaAs, InP, InSb, and InAs. For some such embodiments, the channel region 225 may be a ternary III—V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where a transistor 222 is a P-type metal-oxide-semiconductor (PMOS) transistor), the channel region 225 may advantageously be a group IV material having a high hole mobility, such as, but not limited to Ge or a Ge-rich SiGe alloy. For some example embodiments, the channel region 225 may have a Ge content between 0.6 and 0.9, and advantageously may be at least 0.7.

In some embodiments, the channel region 225 may be a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the channel region 225 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc.

As noted above, the channel region 225 may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors. IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃ (ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

In some embodiments, a transistor 222 may be a thin-film transistor (TFT). A TFT is a special kind of a field-effect transistor (FET) made by depositing a thin film of an active semiconductor material over a support (e.g., a support structure as described above) that may be a non-conducting support. Some such materials may be deposited at relatively low temperatures, which allows depositing them within the thermal budgets to avoid damaging other components such as the logic devices of an IC structure. At least a portion of the active semiconductor material forms a channel of the TFT. In some such embodiments, the channel region 225 may be a semiconductor material deposited at relatively low temperatures and may include any of the oxide semiconductor materials described above.

In other embodiments, instead of having semiconductor materials deposited at relatively low temperatures as described above with reference to the TFTs, the channel region 225 may include one or more semiconductor materials that are epitaxially grown in what typically involves relatively high-temperature processing. In such embodiments, the channel region 225 may include any of the semiconductor materials described above, including oxide semiconductor materials. In some such embodiments, the channel region 225 may be a semiconductor material epitaxially grown directly on a semiconductor layer of the substrate 210, in a process known as “monolithic integration.” In other such embodiments, the channel region 225 may be a semiconductor material epitaxially grown on a semiconductor layer of another support structure and then the epitaxially grown layer of the channel region 225 may be transferred, in a process known as a “layer transfer,” to the substrate 210, in which case the substrate 210 may but does not have to include a semiconductor layer prior to the layer transfer. Layer transfer advantageously allows forming transistors over support structures or in layers that do not include semiconductor materials (e.g., in the backend of an IC device). Layer transfer also advantageously allows forming transistors of any architecture (e.g., non-planar or planar transistors) without imposing the negative effects of the relatively high-temperature epitaxial growth process on devices that may already be present over a support structure.

The semiconductor material of the channel region 225 that is deposited at relatively low temperatures is typically a polycrystalline, polymorphous, or amorphous semiconductor, or any combination thereof. The semiconductor material of the channel region 225 that is epitaxially grown is typically a highly crystalline (e.g., monocrystalline, or single-crystalline) material. Therefore, whether the semiconductor material of the channel region 225 is deposited at relatively low temperatures or epitaxially grown can be identified by inspecting grain size of the active portions of the channel region 225. An average grain size of the semiconductor material of the channel region 225 being between about 0.5 and 1 millimeters (in which case the material may be polycrystalline) or smaller than about 0.5 millimeter (in which case the material may be polymorphous or amorphous) may be indicative of the semiconductor material of the channel region 225 having been deposited using a low-temperature process. On the other hand, an average grain size of the semiconductor material of the channel region 225 being equal to or greater than about 1 millimeter (in which case the material may be a single-crystal material) may be indicative of the semiconductor material of the channel region 225 having been epitaxially grown and included in the IC structure either by monolithic integration or by layer transfer.

The S/D regions 224 may be formed within the substrate 210 adjacent to the gate 226 of each transistor 222, on either side of the channel region 225, using any suitable processes known in the art. For example, the S/D regions 224 may be formed using either an implantation/diffusion process or a deposition process. In the former process, dopants such as boron, aluminum, antimony, phosphorous, or arsenic may be ion-implanted into the substrate 210 to form the S/D regions 224. An annealing process that activates the dopants and causes them to diffuse farther into the substrate 210 may follow the ion implantation process. In the latter process, an epitaxial deposition process may provide material that is used to fabricate the S/D regions 224. In some implementations, the S/D regions 224 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 224 may be formed using one or more alternate semiconductor materials such as germanium or a group III-V material or alloy. In further embodiments, one or more layers of metal and/or metal alloys may be used to form the S/D regions 224. In some embodiments, an etch process may be performed before the epitaxial deposition to create recesses in the substrate 210 in which the material for the S/D regions 224 is deposited.

Each transistor 222 may include a gate 226 that includes a gate electrode material and, in some embodiments, a gate insulator, where the gate insulator may be between the gate electrode material and the channel region 225.

The gate electrode material may include a P-type workfunction metal or N-type workfunction metal, depending on whether the transistor 222 is to be a PMOS or an NMOS transistor, respectively. In some implementations, the gate electrode material may include a stack of two or more metal layers, where one or more metal layers are workfunction metal layers and at least one metal layer is a fill metal layer. Further metal layers may be included for other purposes, such as a barrier layer or/and an adhesion layer. For a PMOS transistor, metals that may be used for the gate electrode material include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 electron Volts (eV) and about 5.2 eV. For an NMOS transistor, metals that may be used for the gate electrode material include, but are not limited to, hafnium, zirconium, titanium, tantalum, aluminum, alloys of these metals, and carbides of these metals such as hafnium carbide, zirconium carbide, titanium carbide, tantalum carbide, aluminum carbide, tungsten, tungsten carbide. An N-type metal layer will enable the formation of an NMOS gate electrode with a workfunction that is between about 3.9 eV and about 4.2 eV.

In some embodiments, when viewed as a cross-section of the transistor 222 along the source-channel-drain direction, the gate electrode material may be formed as a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode material may be formed as a combination of U-shaped structures and planar, non-U-shaped structures. For example, the gate electrode material may be implemented as one or more U-shaped metal layers formed atop one or more planar, non-U-shaped layers. In some embodiments, the gate electrode material may be a V-shaped structure (e.g., when a fin of a FinFET transistor does not have a “flat” upper surface, but instead has a rounded peak).

In some embodiments, the gate insulator may include one or more high-k dielectrics, e.g., insulator materials including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate insulator during fabrication of the IC structures to improve the quality of the gate insulator. The gate insulator may have a thickness that may, in some embodiments, be between about 0.5 nanometers and 10 nanometers, including all values and ranges therein (e.g., between about 0.5 and 3 nanometers, between about 1 and 3 nanometers, or between about 1 and 2 nanometers).

In some embodiments, e.g., when the transistor 222 is a storage transistor of a hysteretic memory cell (i.e., a type of memory that functions based on the phenomenon of hysteresis), the gate insulator may be replaced with, or complemented by, a hysteretic material or a hysteretic arrangement, which, together, may be referred to as a “hysteretic element.” Transistors in which the gate insulator includes a hysteretic element may be described as “hysteretic transistors” and may be used to implement hysteretic memory. Hysteretic memory refers to a memory technology employing hysteretic materials or arrangements, where a material or an arrangement may be described as hysteretic if it exhibits the dependence of its state on the history of the material (e.g., on a previous state of the material). Ferroelectric (FE) and antiferroelectric (AFE) materials are one example of hysteretic materials. Layers of different materials arranged in a stack to exhibit charge-trapping phenomena is one example of a hysteretic arrangement.

A FE or an AFE material is a material that exhibits, over some range of temperatures, spontaneous electric polarization, i.e., displacement of positive and negative charges from their original position, where the polarization can be reversed or reoriented by application of an electric field. In particular, an AFE material is a material that can assume a state in which electric dipoles from the ions and electrons in the material may form a substantially ordered (e.g., substantially crystalline) array, with adjacent dipoles being oriented in opposite (antiparallel) directions (i.e., the dipoles of each orientation may form interpenetrating sub-lattices, loosely analogous to a checkerboard pattern), while a FE material is a material that can assume a state in which all of the dipoles point in the same direction. Because the displacement of the charges in FE and AFE materials can be maintained for some time even in the absence of an electric field, such materials may be used to implement memory cells. Because the current state of the electric dipoles in FE and AFE materials depends on the previous state, such materials are hysteretic materials. Memory technology where logic states are stored in terms of the orientation of electric dipoles in (i.e., in terms of polarization of) FE or AFE materials is referred to as “FE memory,” where the term “ferroelectric” is said to be adopted to convey the similarity of FE memories to ferromagnetic memories, despite the fact that there is typically no iron (Fe) present in FE or AFE materials.

A stack of alternating layers of materials that is configured to exhibit charge-trapping is an example of a hysteretic arrangement. Such a stack may include as little as two layers of materials, one of which is a charge-trapping layer (i.e., a layer of a material configured to trap charges when a volage is applied across the material) and the other one of which is a tunnelling layer (i.e., a layer of a material through which the charge is to be tunneled to the charge-trapping layer). The tunnelling layer may include an insulator material such as a material that includes silicon and oxygen (e.g., silicon oxide), or any other suitable insulator. The charge-trapping layer may include a metal or a semiconductor material that is configured to trap charges. For example, a material that includes silicon and nitrogen (e.g., silicon nitride) may be used in/as a charge-trapping layer. Because the trapped charges may be kept in a charge-trapping arrangement for some time even in the absence of an electric field, such arrangements may be used to implement memory cells. Because the presence and/or the amount of trapped charges in a charge-trapping arrangement depends on the previous state, such arrangements are hysteretic arrangements. Memory technology where logic states are stored in terms of the amount of charge trapped in a hysteretic arrangement may be referred to as “charge-trapping memory.”

Hysteretic memories have the potential for adequate non-volatility, short programming time, low power consumption, high endurance, and high-speed writing. In addition, hysteretic memories may be manufactured using processes compatible with the standard CMOS technology. Therefore, over the last few years, these types of memories have emerged as promising candidates for many growing applications.

In some embodiments, the hysteretic element of the gate insulator may be provided as a layer of a FE or an AFE material. Such an FE/AFE material may include one or more materials that can exhibit sufficient FE/AFE behavior even at thin dimensions, such as an insulator material at least about 5%, e.g., at least about 7% or about 10%, of which is in an orthorhombic phase and/or a tetragonal phase (e.g., as a material in which at most about 95-90% of the material may be amorphous or in a monoclinic phase). For example, such materials may be based on hafnium and oxygen (e.g., hafnium oxides), with various dopants added to ensure sufficient amount of an orthorhombic phase or a tetragonal phase. Some examples of such materials include materials that include hafnium, oxygen, and zirconium (e.g., hafnium zirconium oxide (HfZrO, also referred to as HZO)), materials that include hafnium, oxygen, and silicon (e.g., silicon-doped (Si-doped) hafnium oxide), materials that include hafnium, oxygen, and germanium (e.g., germanium-doped (Ge-doped) hafnium oxide), materials that include hafnium, oxygen, and aluminum (e.g., aluminum-doped (Al-doped) hafnium oxide), and materials that include hafnium, oxygen, and yttrium (e.g., yttrium-doped (Y-doped) hafnium oxide). However, in other embodiments, any other materials which exhibit FE/AFE behavior at thin dimensions may be used as the hysteretic element and are within the scope of the present disclosure.

In other embodiments, the hysteretic element of the gate insulator may be provided as a stack of alternating layers of materials that can trap charges. In some such embodiments, the stack may be a two-layer stack, where one layer is a charge-trapping layer and the other layer is a tunnelling layer. The tunnelling layer may include an insulator material such as a material that includes silicon and oxygen (e.g., silicon oxide), or any other suitable insulator. The charge-trapping layer may include an electrically conductive material such as a metal, or a semiconductor material, that is a charge-trapping material. In some embodiments, the charge-trapping layer may include a material that includes silicon and nitrogen (e.g., silicon nitride). In general, any material that has defects that can trap charge may be used in/as a charge-trapping material. Such defects are very detrimental to operation of logic devices and, therefore, typically, deliberate steps need to be taken to avoid presence of the defects. However, for memory devices, such defects may be desirable because charge-trapping may be used to represent different memory states of a memory cell. In some embodiments, the tunnelling layer may be omitted, and the hysteretic element of the gate insulator may be provided as a charge-trapping material, e.g., a material that includes silicon and nitrogen (e.g., silicon nitride) or, more generally, any material that has defects that can trap charge.

In some embodiments of the hysteretic element being provided as a stack of alternating layers of materials that can trap charges, the stack may be a three-layer stack where an insulator material is provided on both sides of a charge-trapping layer. In such embodiments, a layer of an insulator material on one side of the charge-trapping layer may be referred to as a “tunnelling layer” while a layer of an insulator material on the other side of the charge-trapping layer may be referred to as a “field layer.”

In various embodiments of the hysteretic element being provided as a stack of alternating layers of materials that can trap charges, a thickness of each layer the stack may be between about 0.5 and 10 nanometers, including all values and ranges therein, e.g., between about 0.5 and 5 nanometers. In some embodiment of a three-layer stack, a thickness of each layer of the insulator material may be about 0.5 nanometers, while a thickness of the charge-trapping layer may be between about 1 and 8 nanometers, e.g., between about 2.5 and 7.5 nanometers, e.g., about 5 nanometers. In some embodiments, a total thickness of the hysteretic element provided as a stack of alternating layers of materials that can trap charges (i.e., a hysteretic arrangement) may be between about 1 and 10 nanometers, e.g., between about 2 and 8 nanometers, e.g., about 6 nanometers.

Electrical signals, such as power and/or input/output (I/O) signals, may be routed to and/or from the transistors 222 and other components of the device layer 220 through one or more metal layers 230 disposed on the device layer 220, illustrated in FIG. 3 as metal layers 230-1, 230-2, and 230-3. For example, electrically conductive features of the device layer 220 (e.g., the gate 226 and the S/D contacts 228) may be electrically coupled with the interconnect structures 232 of the metal layers 230. Although a particular number of metal layers 230 is depicted in FIG. 3, embodiments of the present disclosure include IC devices having more or fewer metal layers than depicted. The one or more metal layers 230 may form a metallization stack 240 of the IC structure 300. The metal layers 230 are examples of the metal layers 130 of the IC structure 100A, and the metallization stack 240 is an example of the metallization stack 140 of the IC structure 100A.

The interconnect structures 232, which may also be referred to as “backend interconnect structures” because they are in the metal layers 230 which are in the backend of the IC structure 300, may be arranged within the metal layers 230 to route electrical signals according to a wide variety of designs (in particular, the arrangement is not limited to the particular configuration of interconnect structures 232 depicted in FIG. 3). In some embodiments, the interconnect structures 232 may include conductive lines 232a and/or conductive vias 232b, formed of an electrically conductive material such as a metal. The conductive lines 232a may be arranged to route electrical signals in a direction of a plane that is substantially parallel with a surface of the substrate 210 upon which the device layer 220 is formed. For example, the conductive lines 232a may route electrical signals in a direction in and out of the page from the perspective of FIG. 3. The conductive vias 232b may be arranged to route electrical signals in a direction of a plane that is substantially perpendicular to the surface of the substrate 210 upon which the device layer 220 is formed. In some embodiments, the conductive vias 232b may electrically couple conductive lines 232a of different metal layers 230 together.

A first metal layer 230-1 (referred to as Metal 1 or “M1”) may be formed directly on the device layer 220. In some embodiments, the first metal layer 230-1 may include conductive lines 232a and/or conductive vias 232b, as shown. The conductive lines 232a of the first metal layer 230-1 may be coupled with contacts (e.g., the S/D contacts 228) of the device layer 220.

A second metal layer 230-2 (referred to as Metal 2 or “M2”) may be formed directly on the first metal layer 230-1. In some embodiments, the second metal layer 230-2 may include conductive vias 232b to couple the conductive lines 232a of the second metal layer 230-2 with the conductive lines 232a of the first metal layer 230-1. Although the conductive lines 232a and the conductive vias 232b are structurally delineated with a line within each metal layer (e.g., within the second metal layer 230-2) for the sake of clarity, the conductive lines 232a and the conductive vias 232b may be structurally and/or materially contiguous (e.g., simultaneously filled during a dual-damascene process) in some embodiments.

A third metal layer 230-3 (referred to as Metal 3 or “M3”) (and additional metal layers, as desired) may be formed in succession on the second metal layer 230-2 according to similar techniques and configurations described in connection with the second metal layer 230-2 or the first metal layer 230-1.

The metal layers 230 may include an insulator material 234 disposed between the interconnect structures 232, as shown in FIG. 3. The insulator material 234 may take the form of any of the embodiments of the insulator materials provided between the interconnects of IC structures, for example any of the embodiments discussed herein with reference to the insulating medium of the metallization stack 140. In some embodiments, the insulator material 234 disposed between the interconnect structures 232 in different ones of the metal layers 230 may have different compositions. In other embodiments, the composition of the insulator material 234 in different metal layers 230 may be the same.

The IC structure 300 may include a solder resist material 236 (e.g., polyimide or similar material) and one or more conductive contacts 238 (e.g., bond pads) formed on the metal layers 230. The conductive contacts 238 may be electrically coupled with the interconnect structures 232 and configured to route the electrical signals of the transistor(s) 222 to other external devices. For example, solder bonds may be formed on the one or more conductive contacts 238 to mechanically and/or electrically couple a chip including the IC structure 300 with another component (e.g., a circuit board). The IC structure 300 may have other alternative configurations to route the electrical signals from the metal layers 230 than depicted in other embodiments. For example, the conductive contacts 238 illustrated in FIG. 3 as bond pads may be replaced by or may further include other analogous features (e.g., posts) that route the electrical signals to external components.

FIGS. 3A-3E further illustrate a backend NEMS switch 255 included in the metallization stack 240. The backend NEMS switch 255 is an example of any of the backend NEMS switches 155 of IC structures 100 shown in FIGS. 1A-1J. In all of FIGS. 3A-3E, the middle element 251 of the backend NEMS switch 255 is connected to one of the interconnect structures 232 that is labeled in FIGS. 3A-3E as an interconnect structure A (e.g., one of the conductive lines 232a, although in other embodiments the interconnect structure A could be one of the conductive vias 232b, which holds for all of the interconnect structures A, B, C, and D, described herein with reference to FIGS. 3A-3E). Then, depending on a state of the backend NEMS switch 255, which state may be controlled/affected by application of stimuli to the one or more control elements 257 of the backend NEMS switch 255, the cantilever 253 may move to different positions. A dotted contour shown in FIG. 3A illustrates example of a void 260 in the insulator material 234 that may surround at least a portion of the cantilever 253 to enable mechanical motion of the cantilever 253. Other drawings do not illustrate the void 260, but it is to be understood that the void 260 is also present there, having any suitable shape and location to enable mechanical motion of the cantilever 253 as described herein.

FIG. 3A illustrates an embodiment where the backend NEMS switch 255 may be in a first state or in a second state. In a first state, the cantilever 253 may be in a first position (depicted with the cantilever 253 with a solid line) where it is further connected to an interconnect structure B, thus electrically connecting the interconnect structures A and B. In a second state, the cantilever 253 may be in a second position (depicted with the cantilever 253 with a dashed line) where it is disconnected from the interconnect structure B, thus breaking electrical connectivity between the interconnect structures A and B.

FIG. 3A illustrates an embodiment where, in the second state, the cantilever 253 is not connected to any further interconnect structures besides the interconnect structure A. In other embodiments, in the second state, the cantilever 253 may be connected to another interconnect structure. An example of which is shown in FIG. 3B, illustrating that, in the first state, the cantilever 253 may connect the interconnect structures A and B as in FIG. 3A, but that, in the second state, the cantilever 253 may be in a second position where it is further connected to an interconnect structure C, thus electrically connecting the interconnect structures A and C, but disconnecting the interconnect structures A and B. In the first state of FIG. 3B, the 253 connects the interconnect structures A and B, but disconnects the interconnect structures A and C.

FIG. 3B illustrates an embodiment where, in the second state, the cantilever 253 is connected to the interconnect structure C that is in a plane below the interconnect structure B. In other such embodiments, the interconnect structure C may be in a plane above the interconnect structure B, as is shown in FIG. 3C. In still other embodiments, the backend NEMS switch 255 may be in one of three states, as is shown in FIG. 3D. In the first and second states, the cantilever 253 may be substantially as described with reference to FIG. 3B, and, in a third state, the cantilever 253 may be in a third position where it is further connected to an interconnect structure D (which may be in a different plane than the interconnect structures B and C), thus electrically connecting the interconnect structures A and D, but disconnecting the interconnect structures A and B, and disconnecting the interconnect structures A and C.

FIG. 3E further illustrates an embodiment where, in a first state of the backend NEMS switch 255, the cantilever 253 is disconnected from the interconnect structure B, but is connected to the interconnect structure B in a second state.

Together, FIGS. 3A-3E illustrate that, during operation of a backend NEMS switch 255, the backend NEMS switch 255 may be placed into one of a plurality of different states by applying one or more stimuli to the one or more control elements 257. Each state corresponds to a different position of the cantilever 253 or, phrased differently, depending on the state, the cantilever 253 may be in one of a plurality of different positions within the void 260 within the insulator material 234, where the void 260 is of any suitable shape and size to allow movement of the cantilever 253. For example, a method of operating the backend NEMS switch 255 may include applying one or more stimuli to the one or more control elements 257 to place the NEMS switch 255 in one of a plurality of states, the plurality of states comprising a first state or in a second state, wherein the middle element 251 is connected to a first interconnect structure embedded within the insulator material 234, and wherein, in the first state, the cantilever 253 is connected to a second interconnect structure embedded within the insulator material 234, and in the second state, the cantilever 253 is disconnected from the second interconnect structure. Switching the backend NEMS switch 255 from the first state to the second state may include the cantilever 253 physically moving from a first position to a second position within a void 260 in the insulator material 234.

The IC structures with backend NEMS switches disclosed herein (e.g., any of the IC structures described with reference to FIGS. 1-3) may be included in any suitable electronic device. FIGS. 4-7 illustrate various examples of apparatuses that may include one or more IC structures with backend NEMS switches disclosed herein.

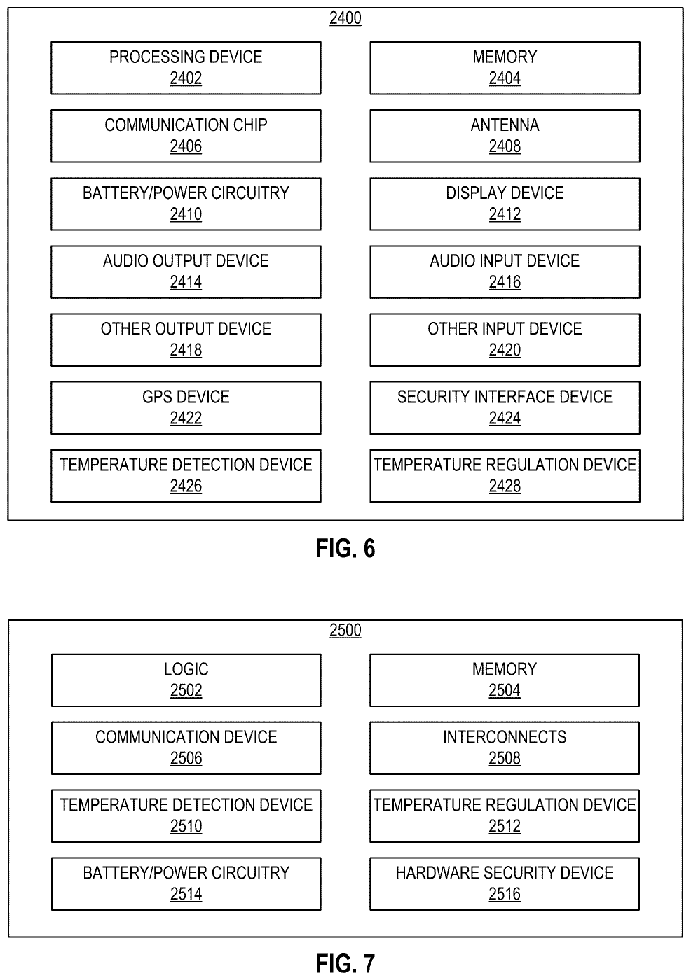

FIG. 4 illustrates top views of a wafer and dies that include one or more IC structures with backend NEMS switches in accordance with any of the embodiments disclosed herein. The wafer 2000 may be composed of semiconductor material and may include one or more dies 2002 having IC structures formed on a surface of the wafer 2000. Each of the dies 2002 may be a repeating unit of a semiconductor product that includes any suitable IC structure (e.g., any of the IC structures described with reference to FIGS. 1-3). After the fabrication of the semiconductor product is complete (e.g., after manufacture of one or more IC structures with one or more backend NEMS switches as described herein), the wafer 2000 may undergo a singulation process in which each of the dies 2002 is separated from one another to provide discrete “chips” of the semiconductor product. In particular, devices that include one or more IC structures with one or more backend NEMS switches as disclosed herein may take the form of the wafer 2000 (e.g., not singulated) or the form of the die 2002 (e.g., singulated). The die 2002 may include one or more transistors (e.g., one or more of the transistors 222 of FIGS. 3A-3E) and/or supporting circuitry to route electrical signals to the transistors, as well as any other IC components (e.g., one or more backend NEMS switches as discussed herein). In some embodiments, the wafer 2000 or the die 2002 may include a memory device (e.g., a static random-access memory (SRAM) device), a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2402 of FIG. 6 or the logic circuitry 2502 of FIG. 7) or other logic that is configured to store information in the memory devices or execute instructions stored in the memory array.

FIG. 5 illustrates a cross-sectional side view of an IC device assembly 2100 that may include components having or being associated with (e.g. being electrically connected by means of) one or more backend NEMS switches in accordance with any of the embodiments disclosed herein. The IC device assembly 2100 includes a number of components disposed on a circuit board 2102 (which may be, e.g., a motherboard). The IC device assembly 2100 includes components disposed on a first face 2140 of the circuit board 2102 and an opposing second face 2142 of the circuit board 2102; generally, components may be disposed on one or both faces 2140 and 2142. In particular, any suitable ones of the components of the IC device assembly 2100 may include any of the backend NEMS switches, disclosed herein.

In some embodiments, the circuit board 2102 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2102. In other embodiments, the circuit board 2102 may be a non-PCB substrate.

The IC device assembly 2100 illustrated in FIG. 5 includes a package-on-interposer structure 2136 coupled to the first face 2140 of the circuit board 2102 by coupling components 2116. The coupling components 2116 may electrically and mechanically couple the package-on-interposer structure 2136 to the circuit board 2102, and may include solder balls (as shown in FIG. 5), male and female portions of a socket, an adhesive, an underfill material, and/or any other suitable electrical and/or mechanical coupling structure.

The package-on-interposer structure 2136 may include an IC package 2120 coupled to an interposer 2104 by coupling components 2118. The coupling components 2118 may take any suitable form for the application, such as the forms discussed above with reference to the coupling components 2116. Although a single IC package 2120 is shown in FIG. 5, multiple IC packages may be coupled to the interposer 2104; indeed, additional interposers may be coupled to the interposer 2104. The interposer 2104 may provide an intervening substrate used to bridge the circuit board 2102 and the IC package 2120. The IC package 2120 may be or include, for example, a die (the die 2002 of FIG. 4), an IC device (e.g., any of the IC structures with backend NEMS switches, described herein, e.g., any of the IC structures illustrated in FIGS. 1-3), or any other suitable component. In some embodiments, the IC package 2120 may include one or more backend NEMS switches, as described herein. Generally, the interposer 2104 may spread a connection to a wider pitch or reroute a connection to a different connection. For example, the interposer 2104 may couple the IC package 2120 (e.g., a die) to a ball grid array (BGA) of the coupling components 2116 for coupling to the circuit board 2102. In the embodiment illustrated in FIG. 5, the IC package 2120 and the circuit board 2102 are attached to opposing sides of the interposer 2104; in other embodiments, the IC package 2120 and the circuit board 2102 may be attached to a same side of the interposer 2104. In some embodiments, three or more components may be interconnected by way of the interposer 2104.

The interposer 2104 may be formed of an epoxy resin, a fiberglass-reinforced epoxy resin, a ceramic material, or a polymer material such as polyimide. In some implementations, the interposer 2104 may be formed of alternate rigid or flexible materials that may include the same materials described above for use in a semiconductor substrate, such as silicon, germanium, and other group III-V and group IV materials. The interposer 2104 may include metal interconnects 2108 and vias 2110, including but not limited to TSVs 2106. The interposer 2104 may further include embedded devices 2114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on the interposer 2104. The interposer 2104 may further include one or more backend NEMS switches as described herein. The package-on-interposer structure 2136 may take the form of any of the package-on-interposer structures known in the art.

The IC device assembly 2100 may include an IC package 2124 coupled to the first face 2140 of the circuit board 2102 by coupling components 2122. The coupling components 2122 may take the form of any of the embodiments discussed above with reference to the coupling components 2116, and the IC package 2124 may take the form of any of the embodiments discussed above with reference to the IC package 2120.

The IC device assembly 2100 illustrated in FIG. 5 includes a package-on-package structure 2134 coupled to the second face 2142 of the circuit board 2102 by coupling components 2128. The package-on-package structure 2134 may include an IC package 2126 and an IC package 2132 coupled together by coupling components 2130 such that the IC package 2126 is disposed between the circuit board 2102 and the IC package 2132. The coupling components 2128 and 2130 may take the form of any of the embodiments of the coupling components 2116 discussed above, and the IC packages 2126 and 2132 may take the form of any of the embodiments of the IC package 2120 discussed above. The package-on-package structure 2134 may be configured in accordance with any of the package-on-package structures known in the art.

FIG. 6 is a block diagram of an example computing device 2400 that may include one or more components including IC structures with backend NEMS switches in accordance with any of the embodiments disclosed herein. For example, any suitable ones of the components of the computing device 2400 may include a die (e.g., the die 2002 of FIG. 4) having one or more backend NEMS switches as described herein. Any one or more of the components of the computing device 2400 may include, or be included in, an IC device assembly 2100 of FIG. 5.

A number of components are illustrated in FIG. 6 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-chip (SoC) die.

Additionally, in various embodiments, the computing device 2400 may not include one or more of the components illustrated in FIG. 6, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. In some embodiments, the processing device 2402 may include one or more backend NEMS switches as described herein. The computing device 2400 may include a memory 2404, which may itself include one or more memory devices such as volatile memory (e.g., DRAM), non-volatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque MRAM. In some embodiments, the memory 2404 may include one or more backend NEMS switches as described herein.

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

FIG. 7 is a block diagram of an example processing device 2500 that may include one or more components including IC structures with backend NEMS switches in accordance with any of the embodiments disclosed herein. For example, any suitable ones of the components of the processing device 2500 may include a die (e.g., the die 2002 of FIG. 4) having one or more IC structures with backend NEMS switches as described herein. Any one or more of the components of the processing device 2500 may include, or be included in, an IC device assembly 2100 (FIG. 5). Any one or more of the components of the processing device 2500 may include, or be included in, a computing device 2400 of FIG. 6; for example, the processing device 2500 may be the processing device 2402 of the computing device 2400.

A number of components are illustrated in FIG. 7 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 7, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504. In some embodiments, the logic circuitry 2502 may include one or more backend NEMS switches described herein.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 6). In some embodiments, the memory 2504 may be a designated device configured to provide storage functionality for the components of the processing device 2500 (e.g., local), while the memory 1604 may be configured to provide system-level storage functionality for the entire computing device 2400 (e.g., global). In some embodiments, the memory 2504 may include memory that shares a die with the logic circuitry 2502. In some embodiments, the memory 2504 may include one or more backend NEMS switches described herein.

The processing device 2500 may include a communication device 2506, which may be implemented substantially as described above with reference to the communication chip 2406 (FIG. 6). In some embodiments, the communication device 2506 may be a designated device configured to provide communication functionality for the components of the processing device 2500 (e.g., local), while the communication chip 2406 may be configured to provide system-level communication functionality for the entire computing device 2400 (e.g., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, MIM structures, etc. In some embodiments, the interconnects 2508 may be implemented as the interconnect structures 232 of FIGS. 3A-3E, described above.

The processing device 2500 may include a temperature detection device 2510 which may be implemented substantially as described above with reference to the temperature detection device 2426 of FIG. 6 but configured to determine temperatures on a more local scale, e.g., of the processing device 2500 of components thereof. In some embodiments, the temperature detection device 2510 may be a designated device configured to provide temperature detection functionality for the components of the processing device 2500 (e.g., local), while the temperature detection device 2426 may be configured to provide system-level temperature detection functionality for the entire computing device 2400 (e.g., global).

The processing device 2500 may include a temperature regulation device 2512 which may be implemented substantially as described above with reference to the temperature regulation device 2428 of FIG. 6 but configured to regulate temperatures on a more local scale, e.g., of the processing device 2500 of components thereof. In some embodiments, the temperature regulation device 2512 may be a designated device configured to provide temperature regulation functionality for the components of the processing device 2500 (e.g., local), while the temperature regulation device 2428 may be configured to provide system-level temperature regulation functionality for the entire computing device 2400 (e.g., global).

The processing device 2500 may include a battery/power circuitry 2514 which may be implemented substantially as described above with reference to the battery/power circuitry 2410 of FIG. 6. In some embodiments, the battery/power circuitry 2514 may be a designated device configured to provide battery/power functionality for the components of the processing device 2500 (e.g., local), while the battery/power circuitry 2410 may be configured to provide system-level battery/power functionality for the entire computing device 2400 (e.g., global).

The processing device 2500 may include a hardware security device 2516 which may be implemented substantially as described above with reference to the security interface device 2424 of FIG. 6. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The following paragraphs provide various examples of the embodiments disclosed herein.

Example 1 provides an IC structure that includes a device layer including a plurality of transistors; one or more backend layers over the device layer, the one or more backend layers including a plurality of backend interconnect structures, where the plurality of backend interconnect structures includes a first backend interconnect structure and a second backend interconnect structure, and where at least one of the plurality of backend interconnect structures is connected to (e.g., is in direct physical contact with, directly electrically connected to, and/or in conductive contact with) to at least one of the plurality of transistors; and a NEMS switch in the one or more backend layers connected to the first backend interconnect structure and including a cantilever, where: in a first state of the NEMS switch, the cantilever is further connected to the second backend interconnect structure, and in a second state of the NEMS switch, the cantilever is disconnected from the second backend interconnect structure.

Example 2 provides the IC structure according to example 1, where the first backend interconnect structure and the second backend interconnect structure are in a single backend layer of the one or more backend layers.

Example 3 provides the IC structure according to example 1, where the first backend interconnect structure and the second backend interconnect structure are in different backend layers of the one or more backend layers.

Example 4 provides the IC structure according to any one of examples 1-3, where: the plurality of backend interconnect structures further includes a third backend interconnect structure, and in the second state of the NEMS switch, the cantilever is connected to the third backend interconnect structure.

Example 5 provides the IC structure according to example 4, where the first backend interconnect structure and the third backend interconnect structure are in different backend layers of the one or more backend layers.

Example 6 provides the IC structure according to any one of examples 4-5, where: the plurality of backend interconnect structures further includes a fourth backend interconnect structure, and in a third state of the NEMS switch, the cantilever is connected to the fourth backend interconnect structure and is disconnected from the second backend interconnect structure and from the third backend interconnect structure.

Example 7 provides the IC structure according to any one of examples 1-6, where the one or more backend layers are over a front side of the device layer.

Example 8 provides the IC structure according to any one of examples 1-6, where the one or more backend layers are over a back side of the device layer.

Example 9 provides the IC structure according to example 8, further including a bonding interface between the back side of the device layer and the one or more backend layers.

Example 10 provides the IC structure according to any one of examples 1-9, where the NEMS switch further includes one or more electrodes to control switching between the first state and the second state.

Example 11 provides an IC structure that includes an insulator material; an interconnect structure embedded in the insulator material; and a conductive switch embedded in the insulator material, the conductive switch including a middle conductive element, a cantilever extending from the middle element, and one or more control conductive elements separated from the cantilever by a gap, where the middle element is connected to the interconnect structure, a void is embedded in the insulator material, and the cantilever is in the void.

Example 12 provides the IC structure according to example 11, where: the interconnect structure is a first interconnect structure, the IC structure further includes a second interconnect structure, the cantilever is to be in one of a plurality of positions in the void, the plurality of positions includes a first position and in a second position, in the first position, the cantilever is connected to the second interconnect structure, and in the second position, the cantilever is disconnected from the second interconnect structure.

Example 13 provides the IC structure according to example 12, where: the IC structure further includes a third interconnect structure, in the second position, the cantilever is connected to the third interconnect structure.

Example 14 provides the IC structure according to any one of examples 11-13, where: the interconnect structure is a first interconnect structure, the IC structure further includes a second interconnect structure, and the cantilever is a moveable cantilever that is either in contact with the second interconnect structure or is spaced from the second interconnect structure.

Example 15 provides the IC structure according to any one of examples 11-14, where: the interconnect structure is a first interconnect structure, the IC structure further includes a second interconnect structure, and depending on a stimulus applied to the one or more control elements, the cantilever is either connected to the second interconnect structure or disconnected from the second interconnect structure.

Example 16 provides the IC structure according to example 15, where the stimulus includes an electrical stimulus, e.g., a voltage.

Example 17 provides the IC structure according to any one of examples 11-16, where the middle element is embedded in the insulator material.

Example 18 provides the IC structure according to any one of examples 11-17, where the one or more control elements are embedded in the insulator material.

Example 19 provides a method of operating a NEMS switch within an IC structure that includes an insulator material, a first interconnect structure embedded in the insulator material, a second interconnect structure embedded in the insulator material, and the NEMS switch including a middle conductive element, a cantilever extending from the middle element, and one or more control conductive elements separated from the cantilever by a gap. The method includes applying one or more stimuli to the one or more control elements to place the NEMS switch in one of a plurality of states, the plurality of states including a first state or in a second state, where: the middle element is connected to the first interconnect structure, in the first state, the cantilever is connected to the second interconnect structure, and in the second state, the cantilever is disconnected from the second interconnect structure.

Example 20 provides the method according to example 19, where switching the NEMS switch from the first state to the second state includes the cantilever physically moving from a first position to a second position within a void in the insulator material.

Example 21 provides an IC package, including an IC die, including an IC structure according to any one of the preceding examples; and a further component, coupled to the IC die.

Example 22 provides the IC package according to example 21, where the further component is one of a package substrate, an interposer, or a further IC die.

Example 23 provides the IC package according to examples 21 or 22, further including an insulator material around at least a portion of the IC die.

Example 24 provides the IC package according to any one of examples 21-23, further including interconnect structures between the further component and the IC die.

Example 25 provides the IC package according to example 24, where the interconnect structures are solder bumps.

Example 26 provides the IC package according to example 24, where the interconnect structures are hybrid bonding interconnect structures.

Example 27 provides the IC package according to any one of examples 24-26, further including first conductive contacts at a surface of the further component closest to the IC die; and second conductive contacts at a surface of the IC die closest to the further component, where the interconnect structures are between the first conductive contacts and the second conductive contacts.

Example 28 provides the IC package according to example 27, where at least one of the first conductive contacts or the second conductive contacts includes a conductive pad.

Example 29 provides the IC package according to example 27, where at least one of the first conductive contacts or the second conductive contacts includes a conductive socket.

Example 30 provides the IC package according to any one of examples 21-29, where: the further component is an interposer, the IC package further includes a package substrate coupled to the interposer, the IC die is coupled to a first face of the interposer, and the package substrate is coupled to a second face of the interposer opposite the first face of the interposer.

Example 31 provides the IC package according to example 30, further including interconnect structures between the interposer and the package substrate.

Example 32 provides the IC package according to example 31, further including an underfill material around the interconnect structures.

Example 33 provides an electronic device, including a carrier substrate; and one or more of the IC structures according to any one of the preceding examples and/or the IC package according to any one of the preceding claims, coupled to the carrier substrate.

Example 34 provides the electronic device according to example 33, where the carrier substrate is a motherboard.

Example 35 provides the electronic device according to example 33, where the carrier substrate is a PCB.

Example 36 provides the electronic device according to any one of examples 33-35, where the electronic device is a wearable electronic device (e.g., a smart watch) or handheld electronic device (e.g., a mobile phone).

Example 37 provides the electronic device according to any one of examples 33-36, where the electronic device further includes one or more communication chips and an antenna.

Example 38 provides the electronic device according to any one of examples 33-37, where the electronic device is memory device.

Example 39 provides the electronic device according to any one of examples 33-37, where the electronic device is one of a RF transceiver, a switch, a power amplifier, a low-noise amplifier, a filter, a filter bank, a duplexer, an upconverter, or a downconverter of an RF communications device, e.g., of an RF transceiver.

Example 40 provides the electronic device according to any one of examples 33-37, where the electronic device is a computing device.

Example 41 provides the electronic device according to any one of examples 33-40, where the electronic device is included in a base station of a wireless communication system.

Example 42 provides the electronic device according to any one of examples 33-40, where the electronic device is included in a user equipment device (i.e., a mobile device) of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a device layer comprising a plurality of transistors;
one or more backend layers over the device layer, the one or more backend layers comprising a plurality of backend interconnect structures, wherein the plurality of backend interconnect structures includes a first backend interconnect structure and a second backend interconnect structure, and wherein at least one of the plurality of backend interconnect structures is connected to at least one of the plurality of transistors; and
a nanoelectromechanical systems (NEMS) switch connected to the first backend interconnect structure and comprising a cantilever, wherein:
in a first state of the NEMS switch, the cantilever is further connected to the second backend interconnect structure, and
in a second state of the NEMS switch, the cantilever is disconnected from the second backend interconnect structure.

2. The IC structure according to claim 1, wherein the first backend interconnect structure and the second backend interconnect structure are in a single backend layer of the one or more backend layers.

3. The IC structure according to claim 1, wherein the first backend interconnect structure and the second backend interconnect structure are in different backend layers of the one or more backend layers.

4. The IC structure according to claim 1, wherein:
the plurality of backend interconnect structures further includes a third backend interconnect structure, and
in the second state of the NEMS switch, the cantilever is connected to the third backend interconnect structure.

5. The IC structure according to claim 4, wherein the first backend interconnect structure and the third backend interconnect structure are in different backend layers of the one or more backend layers.

6. The IC structure according to claim 4, wherein:
the plurality of backend interconnect structures further includes a fourth backend interconnect structure, and
in a third state of the NEMS switch, the cantilever is connected to the fourth backend interconnect structure.

7. The IC structure according to claim 1, wherein the one or more backend layers are over a front side of the device layer.

8. The IC structure according to claim 1, wherein the one or more backend layers are over a back side of the device layer.

9. The IC structure according to claim 8, further comprising a bonding interface between the back side of the device layer and the one or more backend layers.

10. The IC structure according to claim 1, wherein the NEMS switch further includes one or more electrodes to control switching between the first state and the second state.

11. An integrated circuit (IC) structure, comprising:
an insulator material;
an interconnect structure embedded in the insulator material; and
a conductive switch comprising:
a middle element,
a cantilever extending from the middle element, and
one or more control elements separated from the cantilever by a gap,
wherein the middle element is connected to the interconnect structure, a void is embedded in the insulator material, and the cantilever is in the void.

12. The IC structure according to claim 11, wherein:
the interconnect structure is a first interconnect structure,
the IC structure further includes a second interconnect structure,
the cantilever is to be in one of a plurality of positions in the void,
the plurality of positions includes a first position and in a second position,
in the first position, the cantilever is connected to the second interconnect structure, and
in the second position, the cantilever is disconnected from the second interconnect structure.

13. The IC structure according to claim 12, wherein:
the IC structure further includes a third interconnect structure, and
in the second position, the cantilever is connected to the third interconnect structure.

14. The IC structure according to claim 11, wherein:
the interconnect structure is a first interconnect structure,
the IC structure further includes a second interconnect structure, and
the cantilever is a moveable cantilever that is either in contact with the second interconnect structure or is spaced from the second interconnect structure.

15. The IC structure according to claim 11, wherein:
the interconnect structure is a first interconnect structure,
the IC structure further includes a second interconnect structure, and
depending on a stimulus applied to the one or more control elements, the cantilever is either connected to the second interconnect structure or disconnected from the second interconnect structure.

16. The IC structure according to claim 15, wherein the stimulus includes an electrical stimulus.

17. The IC structure according to claim 11, wherein the middle element is embedded in the insulator material.

18. The IC structure according to claim 11, wherein the one or more control elements are embedded in the insulator material.

19. A method of operating a nanoelectromechanical systems (NEMS) switch within an integrated circuit (IC) structure that includes an insulator material, a first interconnect structure embedded in the insulator material, a second interconnect structure embedded in the insulator material, and the NEMS switch including a middle element, a cantilever extending from the middle element, and one or more control elements separated from the cantilever by a gap, the method comprising:
applying one or more stimuli to the one or more control elements to place the NEMS switch in one of a plurality of states, the plurality of states comprising a first state or in a second state,
wherein:
the middle element is connected to the first interconnect structure,
in the first state, the cantilever is connected to the second interconnect structure, and
in the second state, the cantilever is disconnected from the second interconnect structure.

20. The method according to claim 19, wherein switching the NEMS switch from the first state to the second state includes the cantilever physically moving from a first position to a second position within a void in the insulator material.
